(19) United States
(12) Patent Application Publication
(10) Pub. No.: US 2025/0107202 A1
(43) Pub. Date: Mar. 27, 2025

(54) Transistor Device

(71) Applicant: Infineon Technologies AG, Neubiberg (DE)

(72) Inventors: Thomas Aichinger, Faak am See (AT); Hans Weber, Villach (AT); Michael Hell, Erlangen (DE); Wolfgang Bergner, Klagenfurt am Wörthersee (AT); Armin Tilke, Dresden (DE); Grazvydas Ziemys, München (DE); Alexey Mikhaylov, Villach (AT); Gerald Rescher, Maria Saal (AT)

(21) Appl. No.: 18/882,226

(22) Filed: Sep. 11, 2024

(30) Foreign Application Priority Data
Sep. 27, 2023 (DE) 102023126381.1

(51) Int. Cl. H01L 29/40; H01L 29/16; H01L 29/423; H01L 29/51; H01L 29/78

(52) U.S. Cl. CPC H10D 64/117; H10D 30/668; H10D 64/514; H10D 64/681; H10D 62/8325

(57) ABSTRACT

A transistor device is disclosed. The transistor device includes a semiconductor body and plurality of transistor cells. Each transistor cell includes: a drift region and a source region of a first doping type; a body region of a second doping type complementary to the first doping type; a field shaping region of the second doping type connected to a source node; and a gate electrode connected to a gate node. The gate electrode is arranged in a trench extending from a first surface into the semiconductor body. The gate electrode is dielectrically insulated from the body region by a gate dielectric. At least portions of the gate electrode are dielectrically insulated from the drift region by a field dielectric. The field shaping region adjoins the trench. The field dielectric comprises a high-k dielectric.

### TECHNICAL FIELD

This disclosure relates in general to a transistor device, in particular a silicon carbide (SiC) based transistor device.

### BACKGROUND

Silicon carbide (SiC) has a higher bandgap than silicon (Si), so that SiC is capable of withstanding higher electric fields than silicon. Thus, in a SiC based vertical transistor device with a given voltage blocking capability the length of the drift region can be reduced as compared to a silicon based vertical transistor device with the same voltage blocking capability. The reduced length of the drift region results in a lower on-resistance of the SiC device as compared to the silicon device. The reduction of the on-resistance, which is the electrical resistance of the transistor device in the on-state results in lower conduction losses and is an ongoing goal in the design of transistor devices.

A vertical SiC transistor device can be implemented with trench gate electrodes, which are gate electrodes that are arranged in trenches extending from a surface into a SiC semiconductor body. The trench gate electrodes are dielectrically insulated from the semiconductor body by a gate dielectric.

High electric fields that may occur in a SiC based transistor device may damage the gate dielectric. Conventional SiC based transistor devices therefore include doped regions of a doping type complementary to the doping type of the drift region and connected to a source node (source electrode) of the transistor device. These doped regions are located below the gate trenches and, together with the drift region, form a JFET that, in a blocking state of the transistor device, protects the gate dielectric from high electric fields.

Between the drift region and the JFET regions the device includes pn-junctions. Such pn-junctions, even in an on-state of the transistor device, involve space-charge regions (depletion regions), which reduce a width of an electrically conducting path of the transistor device in the on-state. This limits the minimal possible cell pitch, even if perfectly shaped JFET regions would be possible.

There is therefore a need for an improved SiC based transistor device.

### SUMMARY

One example relates to a transistor device. The transistor device includes a semiconductor body and plurality of transistor cells. Each transistor cell includes a drift region and a source region of a first doping type, a body region of a second doping type complementary to the first doping type, a field shaping region of the second doping type connected to the source node, and a gate electrode connected to a gate node. The gate electrode is arranged in a trench extending from a first surface into the semiconductor body and is dielectrically insulated from the body region by a gate dielectric. At least portions of the gate electrode are dielectrically insulated from the drift region by a field dielectric. The field shaping region adjoins the trench. The field dielectric includes a high-k dielectric.

The field shaping region, in a vertical direction of the semiconductor body, may extend deeper into the semiconductor body than the trench.

According to one example, the body region is connected to the source node, and the field shaping region adjoins the body region to be connected to the source node via the body region. According to another example, the body region is connected to the source node via a contact region having a higher doping concentration than the remainder of the body region, and the field shaping region adjoins the contact region to be connected to the source node via the contact region.

In each case, the field shaping region may include a plurality of first sections that are spaced apart from each other along a sidewall of the trench and that are each connected to the source node. The first sections, in a vertical direction of the semiconductor body) extend farther in the direction of the first surface than the drift region. The field shaping region may further comprise second sections that adjoin the first sections and are spaced apart from the body region.

According to one example, the field dielectric is symmetrical relative to a center plane of the trench. According to another example, the field dielectric is asymmetrical relative to a center plane of the trench.

A transistor device according to another example includes a semiconductor body and plurality of transistor cells. Each transistor cell includes a drift region and a source region of a first doping type, a body region of a second doping type complementary to the first doping type, and a gate electrode connected to a gate node. The gate electrode and the field electrode are arranged in a trench extending from a first surface into the semiconductor body, the field electrode is dielectrically insulated from the gate electrode in the trench, the gate electrode is dielectrically insulated from the body region by a gate dielectric, the field electrode is dielectrically insulated from the drift region by a field dielectric, and the field dielectric comprises a high-k dielectric.

The transistor device may further include a field shaping region of the second doping type connected to the source node. The field shaping region may adjoin the trench and, in a vertical direction of the semiconductor body, may extend deeper into the semiconductor body than the trench. The field electrode may be connected to the source node.

In each of the transistor devices, each transistor cell may further include a compensation region of the second doping type adjoining the drift region. The compensation region may adjoin the field shaping regions.

Furthermore, in each of the transistor devices, a maximum thickness of the gate dielectric may be smaller than a maximum thickness of the field dielectric. The gate dielectric may include silicon dioxide or a high-k dielectric.

Furthermore, in each of the transistor devices, a relative dielectric constant of the high-k dielectric is higher than 5, higher than 10, or higher than 20. In each case, the semiconductor body may be a SiC semiconductor body.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 shows a vertical cross-sectional view of a transistor device with a plurality of transistor cells that each include a field dielectric and a field shaping region according to one example;

FIG. 2 schematically illustrates equipotential lines of the electric field in a transistor device of the type illustrated in FIG. 1 when the transistor device is in a blocking state (off-state);

FIGS. 3A and 3B show horizontal cross-sectional views of transistor devices of the type illustrated in FIG. 1 according to different examples;

FIG. 4 shows a vertical cross-sectional view of a transistor device of the type illustrated in FIG. 1 that is implemented as a superjunction device;

FIG. 5 shows a modification of the transistor device according to FIG. 1;

FIGS. 6A and 6B show horizontal cross-sectional views of transistor devices of the type illustrated in FIG. 5 according to different examples;

FIGS. 7-8 show further modifications a transistor device of the type illustrated in FIG. 1;

FIGS. 9A and 9B illustrate examples for connecting source and body regions of the transistor cells to a source node of the transistor device;

FIGS. 10A-10C illustrates another example for connecting the source and body regions of the transistor cells to the source node;

FIG. 11 shows a vertical cross-sectional view of a transistor device with a plurality of transistor cells that each include a field electrode;

FIG. 12 shows a horizontal cross-sectional view of a transistor device of the type illustrated in FIG. 12 according to one example; and

FIG. 13 shows a top view of the transistor device according to one example.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

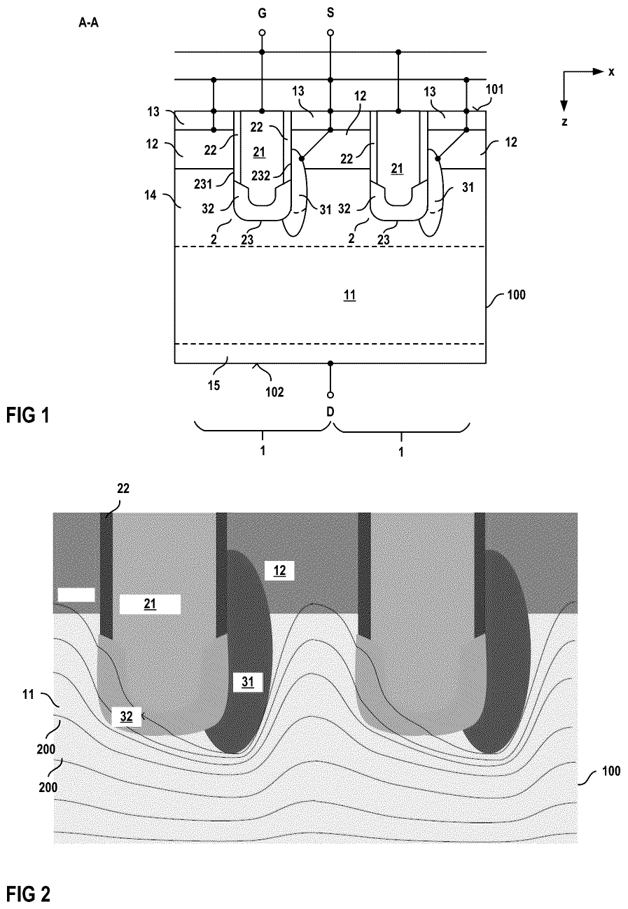

FIG. 1 shows a transistor device according to one example. More specifically, FIG. 1 shows a vertical cross-sectional view of one portion of the transistor device. The transistor device includes a semiconductor body 100 and a plurality of transistor cells 1. The semiconductor body 100 includes a first surface 101 and a second surface 102. The second surface 102 is opposite the first surface 101 and is spaced apart from the first surface 101 in a vertical direction z of the semiconductor body 100.

According to one example, the semiconductor body 100 is a monocrystalline semiconductor body. According to one example, the semiconductor body 100 includes monocrystalline silicon carbide (SiC). According to one example, the monocrystalline SiC is monocrystalline SiC of the 4H polytype, 3H polytype, or 6H polytype. Implementing the semiconductor body 100 with monocrystalline SiC, however, is only an example. Other semiconductor materials, such as silicon (Si), may be used as well.

Referring to FIG. 1, each transistor cell includes a drift region 11, a body region 12, and a source region 13. Each of the drift region 11, the body region 12, and the source region 13 is a doped semiconductor region and arranged within the semiconductor body 100. The drift and source regions 11, 13 are doped regions of a first doping type (conductivity type), and the body region 12 is a doped region of a second doping type (conductivity type) complementary to the first doping type. According to one example, the body region 12 adjoins both the source region 13 and the drift region 11, wherein the body region 12 is arranged between the source region 13 and the drift region 11. The source region 13 and the body region 12 of each transistor cell 1 is connected to a source node S.

The transistor device illustrated in FIG. 1 is a vertical transistor device. This includes that the body region 12 of each transistor cell, in the vertical direction z of the semiconductor body 100, is arranged between the source region 13 and the drift region 11. Furthermore, the drift region 11, in the vertical direction z, is arranged between the body region 12 and an optional drain region 15 explained herein below.

In the following, body regions 12, source regions 13, and drift regions 11 are referred to as “active device regions”. According to one example, doping concentrations of the active device regions are selected from the following ranges, drift region 11: between 5E14 cm⁻³ and 5E17 cm⁻³; body region 12: between 1E16 cm⁻³ and 1E18 cm⁻³; source region 13: higher than 1E19 cm⁻³.

Furthermore, each transistor cell 1 includes a gate electrode 21. The gate electrode 21 is arranged adjacent to the body region 12, is dielectrically insulated from the body region 12 by a dielectric layer 22, which is briefly referred to as gate dielectric in the following, and is connected to a gate node G. Furthermore, the gate electrode 21 is arranged in a trench 23 that, from the first surface 101, extends into the semiconductor body 100. The trench 23 including the gate electrodes 21 is also referred to as gate trench in the following.

According to one example, the gate electrode 21 essentially extends in the vertical direction of the semiconductor body 100. The first trench 23 is spaced apart from the second surface 102. According to one example, the gate electrode 21 includes a metal or a highly doped polycrystalline semiconductor material such as, for example, polysilicon.

Referring to FIG. 1, each transistor cell 1 further includes a field shaping region 31 of the second doping type. The field shaping region 31 is connected to the source node S and adjoins the gate trench 23. The field shaping region 31 serves to shape the field in the drift region 11 when the transistor device is in a blocking state. This is explained in detail herein further below. A connection between the field shaping region 31 and the source node S is only schematically illustrated in FIG. 1 by a connection line running between the field shaping region 31 and the source node S. The connection between the field shaping region 31 and the source node S may be implemented in various ways. Examples for connecting the field shaping the region 31 to the source node S are explained in detail herein further below with reference to further examples.

According to one example illustrated in the solid lines in FIG. 1, the field shaping region 31, in the vertical direction z, extends deeper into the semiconductor body 100 than the gate trench and 23. That is, a lower end of the field shaping regions 31, which is an end of the field shaping region 31 facing away from the first surface 101 is more distant to the first surface 101 than a bottom of the trench 23.

According to another example illustrated in dashed lines in FIG. 1, the field shaping regions 31, in the vertical direction z, extends less deep into the semiconductor body 100 than the gate trenches 23.

According to one example, a doping concentration of the field shaping region 31 is such that the field shaping region 31, in a blocking state of the transistor device, cannot completely be depleted of charge carriers. According to another example, the doping concentration of the field shaping region 31 is such that the field shaping region 31, in the blocking state, can completely be depleted of charge carriers. In this example, the doping concentration is in a range of between 1E15 cm⁻³ and 1E17 cm⁻³, for example.

Furthermore, at least portions of the gate electrode 21 of each transistor cell are dielectrically insulated from the drift region 11 by a further dielectric layer 32. In those regions of the gate trench 23 in which the gate electrode 21 is adjacent to the drift region 11, the gate electrode 21 acts as a field electrode. The further dielectric layer 32 separating the gate electrode 21 from the drift region 11 is briefly referred to as field dielectric 32 in the following. According to one example, “at least portions of the gate electrodes 21 being insulated from the drift region 11 by the field dielectric 32” includes that the field dielectric 32 is arranged between the gate electrode 21 and the drift region 11 at least in those regions of a bottom of the gate trench 23 where the field shaping region 31 does not adjoin the bottom of the gate trench 23. The bottom of the gate trench 23 is that portion of the gate trench 23 that faces the second surface 102.

It should be noted that not the entire portion of the gate electrode 21 that is located adjacent to the drift region 11 is insulated from the drift region 11 by the field dielectric 32. Instead, as illustrated in FIG. 1, portions of the gate electrode 21 may also be insulated from the drift region 11 by the gate dielectric 22. This applies, in particular, to those portions of the gate electrode that are close to a PN junction between the body region 12 and the drift region 11.

The field dielectric 32 is a high-k dielectric. According to one example, this includes that a relative dielectric constant K of the field dielectric 32 is higher than the relative dielectric constant of silicon dioxide (SiO₂), which has a relative dielectric constant of about 3.9, K_{SiO2}≈3.9. According to one example, the material of the field dielectric 32 is selected such that the relative dielectric constant K of the field dielectric 32 is higher than 5, higher than 10, higher than 20, or even higher than 30. The relative dielectric constant of the high-k dielectric may also be referred to as K factor.

Examples of materials for implementing the field dielectric 32 include, but are not restricted to, Al₂O₃ (aluminum oxide) having a K factor of about 9, ZrO₂ (zirconium oxide) having a K factor of about 25, HfO₂ (hafnium oxide) having a K factor of about 25, silicon doped HfO₂, AlN (aluminum nitride), AlSiOₓ (aluminum silicate) having a K factor of between 7 and 10, TiO₂ (titanium oxide), Y₂O₃ (yttrium oxide) having a K factor of about 16, or Si₃N₄ (silicon nitride). The field dielectric 32 may be comprised entirely of the same material, such as one of the materials explained before. According to another example, the field dielectric 32 includes a layer stack with two or more different dielectric layers. At least one of these two or more layers may include one of the high-k materials explained before.

According to one example, the gate dielectric 22 includes silicon oxide (SiO₂). According to another example, the gate dielectric 22 includes a high-k dielectric. The material of the high-k dielectric may be in accordance with one of the examples explained with reference to the field dielectric 32 herein before.

According to one example, the field dielectric 32 is thicker than the gate dielectric 22, that is, the field dielectric 32 has a greater thickness than the gate dielectric 22. The thickness of the field dielectric 32 is given by a shortest distance between the gate electrode 21 and semiconductor material of the semiconductor body 100 in the region of the field dielectric 32. The thickness of the gate dielectric 22 is given by a shortest distance between the gate electrode 21 and the material of the semiconductor body 100 in the region of the gate dielectric 22. In absolute values, the thickness of the gate dielectric 22 is between 20 nm and 150 nm, for example.

In FIG. 1, the gate and source nodes G, S, connections between the gate electrodes 21 of the individual transistor cells 1 and the gate node G, and connections between the source and body regions 13, 12 and the source node S are only schematically illustrated. The gate and source nodes may be implemented using conventional metallizations, and the connections may be implemented using conventional wiring techniques. One example for implementing such circuit nodes and such connections are explained herein further below.

Referring to FIG. 1, the transistor device may further include a drain node D. The drain node D, which is only schematically illustrated in FIG. 1, is electrically connected to the drift region 11 of each transistor cell 1. According to an example illustrated in dashed lines in FIG. 1, the drain node D is connected to the drift region 11 via the drain region 15. According to one example, the drain region 15 is of the same doping type as the drift region 11 and has a higher doping concentration. According to one example, the doping concentration of the drain region 15 is at least 100 times the doping concentration of the drift region 11. According to one example, the doping concentration of the drain region 15 is higher than 5E18 cm⁻³.

In FIG. 1, several transistor cells 1 of the transistor device are illustrated. As can be seen from FIG. 1, two (or more) transistor cells may share an active device region 11, 12, 13, 15. In the example illustrated in FIG. 1, for example, the drift regions 11 of the plurality of transistor cells are be formed by one and the same doped region of the semiconductor body 100. Equivalently, the drain regions 15 of the transistor cells 1 may be formed by one and the same doped region of the semiconductor body 100.

The transistor device can be implemented as an n-type transistor device or as a p-type transistor device. In an n-type transistor device, the doped regions of the first doping type (drift and source regions 11, 13) are n-type regions and the doped regions of the second doping type (body regions 12, field shaping regions 31) are p-type regions. In a p-type transistor device, the drift and source regions 11, 13 are p-type regions and the body regions 12 are n-type regions.

Furthermore, the transistor device can be implemented as an enhancement device or as a depletion device. In an enhancement device, the body region 12 of each transistor cell 1 adjoins the gate dielectric 22 of the respective transistor cell (as illustrated in FIG. 1). In a depletion device, each transistor cell 1, in addition to the body region 12, includes a channel region of the same doping type as the source region 13 between the body region 12 and the gate dielectric 22. Such channel region, however, is not illustrated in FIG. 1.

The transistor device according to FIG. 1 can be operated in a conventional way by applying a drive voltage (gate-source voltage) between the gate node G and the source node S. The transistor device is in an on-state (conducting state) when a drive voltage is applied between the gate node G and the source node S that, in each transistor cell 1, causes a conducting channel in the body region 12 along the gate dielectric 22 between the source region 13 and the drift region 11. An n-type transistor device, for example, is in the on-state when a positive drive voltage higher than the threshold voltage is applied between the gate and source nodes G, S.

In the on-state, a current can flow, in each transistor cell one, from the source node S via the source regions 13, the conducting channel in the body region 12, and the drift region 11 to the drain node D.

In order to more evenly distribute the current in the drift region 11 when the transistor device is in the on-state, the drift region 11 may include a current spreading region 14. The current spreading region 14 is a portion of the drift region 11 and has a higher doping concentration than the remainder of the drift region 11. According to one example, the doping concentration of the current spreading region 14 is between 2 times and 100, in particular between 3 times and 10 times, of the doping concentration of the remainder of the drift region 11.

In the example illustrated in FIG. 1, in each transistor cell 1, the current spreading region 14 adjoins the body region 12. This, however, is only an example. It is also possible to implement the current spreading region 14 in such a way that the current spreading region 14 is spaced apart from the body region 12 in the vertical direction z.

Referring to FIG. 1, the gate trenches 23 with the gate electrodes 21 extend into the drift region 11. According to one example the current spreading region 14, as seen from the first surface 101, extends deeper into the semiconductor body 100 in the vertical direction z than the gate trenches 23 and the field shaping regions 31.

The transistor device is in the off-state when the conducting channels in the body regions 12 are interrupted. In the off-state, when a voltage is applied between the drain and source nodes D, S that reverse biases PN junctions between the body and drift regions 12, 11 of the individual transistor cells 1, a space charge region (depletion region) expands in the drift region 11, and in the body region 12. Such depletion region is associated with an electric field.

A maximum of the electric field may occur in the drift region 11 close to the PN junctions between the body regions 12 and the drift region 11 and, therefore, close to the gate trenches 23 with the gate electrodes 21. If, for example, in the off-state, the electrical potential of the gate electrodes 21 equals the electrical potential of the source and body regions 13, 12, the vertical component of the electric field E₂₂ in the gate dielectric 22 is approximately given by

$${E}_{22} \approx \frac{{ε}_{11}}{{ε}_{22}} \cdot {E}_{11} , \qquad ( 1 )$$

where ε₁₁ denotes the relative dielectric constant (K factor) of the semiconductor material of the semiconductor body 100, ε₂₂ denotes the relative dielectric constant (K factor) of the dielectric material of the gate dielectric 22, and E₁₁ denotes the magnitude of the electric field in the drift region 11 in a region adjoining the gate dielectric 22. Referring to the above, the gate dielectric 22 may include silicon oxide (SiO₂), which has a relative dielectric constant of about 3.9.

The vertical component of the electric field is that component of the electric field that is essentially perpendicular to the interface between the semiconductor material of the semiconductor body 100 and the field dielectric 32.

Silicon carbide of the 4H polytype, for example, has a relative dielectric constant of about 9.6. Thus, if the semiconductor material of the semiconductor body 100 includes silicon carbide and the gate dielectric 22 includes silicon oxide, in accordance with equation (1) the dielectric field E₂₂ in the silicon oxide may be significantly higher (about 2.5 times) than the dielectric field in the adjoining semiconductor material. This may have the effect that the electric field in the gate dielectric 22 may become higher than the critical electric field of the gate dielectric.

The critical electric field of silicon carbide is between 2 MV/cm and 3 MV/cm. The critical electric field for intrinsic breakdown of silicon oxide is between 8 MV/cm and 10 MV/cm, which is more than 2.5 times the critical electric field of silicon carbide. However, due to trench topography and imperfections in the manufacturing process of the gate dielectric 22, the save operating electric field of the gate dielectric 22 may be less than the theoretical critical electric field of the material used to implement the gate dielectric 22. Thus, in order to achieve a reliable device, the electric field in the dielectric layer separating the gate electrode 21 from the drift region 11 should not exceed a certain value, which is 2 times the critically electric field of the material of the semiconductor body 100, for example.

In the transistor device 1 according to FIG. 1, the gate electrodes 21, in the off-state of the transistor device, generate a space charge region (depletion region) in the drift region 11 in those sections that adjoin the gate trenches. This is due to the fact that in the off-state the electrical potential of the gate electrodes 21 is much lower than the electrical potential in the drift region 11. According to one example, the electrical potential of the gate electrodes 21 in the off-state essentially equals the electrical potential of the source node S.

Referring to the above, the field dielectric 32 is arranged between portions of the gate electrode 21 and the drift region 11 and, therefore, is arranged in a region where the highest electric field may occur when the transistor device is in the off-state. Due to the high K factor (higher than 4) of the high-k dielectric the electric field occurring in the field dielectric 32, under the same operating conditions, is lower than the comparable electric field in a transistor device in which the field dielectric is replaced by a dielectric layer comprising a conventional gate dielectric material, such as silicon oxide. Thus, implementing the dielectric layer 32 that separates at least portions of the gate electrode 21 from the drift region 11 using a high-k dielectric increases the robustness of the transistor device as compared to a conventional transistor device in which the dielectric separating the gate electrode from the drift region is made of the same material as the gate dielectric.

Moreover, the gate electrodes 21 in combination with the field dielectrics 32 act as field electrodes that shape the electric field in the drift region 11 in sections adjoining the gate trenches 23 and, therefore, also in sections in which the drift region 11 adjoins the body regions 12. In particular, the gate electrodes 21 in combination with the field dielectrics 32 shape the electric field in the drift region 11 such that the electric field and close to the body regions 13 is low enough to avoid that the gate dielectric 22, which may adjoin the drift region 11 close to the body regions 13, is not damaged when the transistor device is in the blocking state.

Furthermore, the presence of the field shaping regions 31 reduces the gate-drain capacitance of the transistor device, which is a capacitance of the transistor device between the gate node G and the drain node D. The gate-drain capacitance is charged when the transistor device switches off and discharged when the transistor device switches on. Charging and discharging the gate-drain capacitance is as associated with losses, which are a portion of the switching losses of the transistor device. Basically, the higher the gate-drain capacitance and the higher the voltage associated with charging the gate-drain capacitance the higher the switching losses. Thus, reducing the gate-drain capacitance helps to reduce switching losses that may occur in the transistor device.

On the other hand, the presence of the field shaping region 31 increases the gate-source capacitance, which is a capacitance between the gate node G and the source node S. The gate-source capacitance is charged when the transistor device switches on and discharged when the transistor device switches off. Voltages associated with charging the gate-source capacitance, however, are usually lower than voltages as associated with charging the gate-drain capacitance. Voltages associated with charging the gate-source capacitance are usually lower than 20 or 30 V, for example, while voltages associated with charging the gate-drain capacitance may be in the range of several hundred volts.

Thus, in the overall review, reducing the gate-drain capacitance and, at the same time, increasing the gate-source capacitance, helps to reduce switching losses that may occur in the transistor device. Furthermore, reducing the gate-drain capacitance and increasing the gate-source capacitance reduces a ratio Cgd/Cgs between the gate-drain capacitance and the gate-source capacitance. When the transistor device is used as an electronic switch and has been switched off, a low Cgd/Cgs ratio may help to prevent parasitic switching on induced by a rapidly increasing voltage between the drain and source nodes.

Furthermore, the field shaping regions 31 that are connected to the source node S together with the drift region 11 form a body diode

The field shaping effect of the gate electrode 21 in combination with the field dielectric 32 is enhanced by the field shaping regions 31 that, in the vertical direction z, extend deeper into the drift region 11 then the gate trenches 23 with the gate electrodes 21. This is illustrated in FIG. 2.

FIG. 2 illustrates the electric field in the drift region 11 close to the gate trenches in the blocking state of the transistor device. More specifically, FIG. 2 illustrates equipotential lines 200 of the electric field that may occur in the blocking state of the transistor device. As can be seen from FIG. 2, the field shaping regions 31 “push” the equipotential potential lines away from the field dielectric 32. In this way, the field shaping regions 31 have a positive effect in view of reducing the electric field in the gate dielectric 22 and in the regions of the PN junctions between the body regions 13 and the drift region 11.

Referring to the above, the field shaping regions 31 may be implemented such that the doping concentration is so high that the field shaping regions 31 are not completely depleted of charge carriers when the transistor device is in the blocking state and a maximum voltage is applied between the drain and source nodes. The “maximum voltage” is the highest voltage the transistor device can withstand. In this case, as illustrated in FIG. 2, large portions of the field shaping regions 31 are devoid of an electric field.

According to another example, a doping concentration of the field shaping regions 31 is such that the field shaping regions 31 can completely be depleted of charge carriers when the transistor device is in the off-state. In this case, an electric field may also occur in the field shaping regions 31. Nevertheless, the field shaping regions 31 shape the electric field in the drift region 11 such that the electric field in the drift region 11 close to the gate dielectric 11 is reduced.

The dimensions of the field shaping regions 31 can be smaller than the dimensions of JFET regions in a conventional transistor device. In particular, a distance between the bottom of the gate trench 23 and a bottom of the field shaping region 31 adjoining the gate trench 23 can be smaller than a corresponding distance in a conventional transistor device. Furthermore, dimensions of the field shaping regions 31 in lateral directions facing away from the gate trenches 23 can be smaller than corresponding dimensions in a conventional transistor device. Thus, as compared to a conventional transistor device, the pitch, which is given by a center-to-center distance between two neighboring gate trenches 23, for example, can be reduced, so that a higher number of transistor cells can be implemented on the same area. The latter either results in a reduced size of the transistor device at given on-resistance or results in a reduced on-resistance at a given size. The on-resistance is the electrical resistance of the transistor device in the on-state.

According to one example, widths of the field shaping regions 31, which are dimensions of the field shaping regions 31 in the lateral direction x, are less than 50%, less than 25%, less than 10%, or even less than 5% of a shortest distance between two neighboring gate trenches 23. According to one example, in absolute values, the widths of the field shaping regions 31 in the lateral direction x are less than 200 nanometers, or even less than 100 nanometers.

Referring to the above, the field shaping regions 31 may extend deeper into the semiconductor body 100 than the gate trench is 23. In this example, a dimension of portions of the field shaping region 31 that, in the vertical direction z, extend beyond the trench bottom is between 100 nanometers and 500 nanometers, for example.

According to one example, a (shortest) distance between two neighboring gate trenches 23 is selected from between 0.5 micrometers and 2 micrometers. A trench width, which is a (smallest) dimension of the gate trench 23 in a first lateral direction x is between 0.3 micrometers and 1.0 micrometer, for example. Based on this, the pitch, which is given by a center-to-center distance of two neighboring gate trenches 23 (and is given by the trench width plus the trench distance) is between 0.8 micrometers and 3.0 micrometers, for example.

The voltage blocking capability of the transistor device is, inter alia, dependent on a length of the drift region 11. The length of the drift region 11 is essentially given by the (shortest) distance between the body regions 12 and the drain region 15. According to one example, the length of the drift region 11 is selected from between 2 micrometers and 30 micrometers. A SiC based transistor device can be implemented such that the voltage blocking capability essentially equals 150V per 1 μm length of the drift region (as compared to silicon, where the voltage blocking capability is only about 10V to 15V per 1 μm length of the drift region).

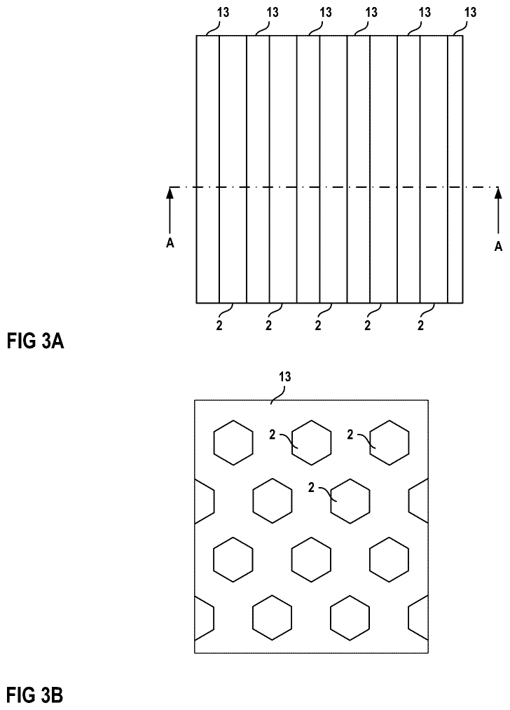

FIG. 1 shows a vertical cross-sectional view of several transistor cells 1. In a horizontal plane, which is a plane that is essentially parallel to the first and second surfaces 101, 102 and vertical to section plane A-A illustrated in FIG. 1, the transistor cells 1 may be implemented in various ways. Examples that illustrates the transistor device in a horizontal plane cutting through the source regions 13 are illustrated in FIGS. 3A and 3B.

In FIGS. 3A and 3B, reference number 2 denotes gate structures that each include a gate electrode 21, a gate dielectric 22, and the field dielectric 32, wherein the gate electrodes 21, the gate dielectrics 22, and the field dielectrics 32 are not explicitly illustrated in FIGS. 3A and 3B.

Referring to FIG. 3A, the transistor cells 1 may be implemented as elongated transistor cells, which may also be referred to as stripe cells. In this example, the gate structures 2 (with the gate electrodes, the gate dielectrics, and the field dielectrics) are elongated in a horizontal (lateral) direction of the semiconductor body 100. Equivalently, the source regions 13 and the body regions 12 (which are out of view in FIG. 3) are elongated, wherein each source and body region 13, 12 is arranged between two neighboring gate trenches 23.

According to another example illustrated in FIG. 3B, the transistor cells 1 may be implemented as hexagonal transistor cells. In this example, the gate trenches 23 have a hexagonal cross-section in the horizontal section plane of the semiconductor body 100, which is a section plane that is essentially parallel to the first surface 101.

Referring to the above, the semiconductor body 100 may include monocrystalline SiC of the 4H or 6H polytype. In this example, the gate structure 2 may be arranged within the crystal of the monocrystalline SiC semiconductor body such that the channel regions (which form in the body regions 12 along the gate dielectrics 22 when the transistor device is in the on-state) are aligned to match vertical crystal planes of the semiconductor body. This is beneficial in view of a reduction of the channel resistance.

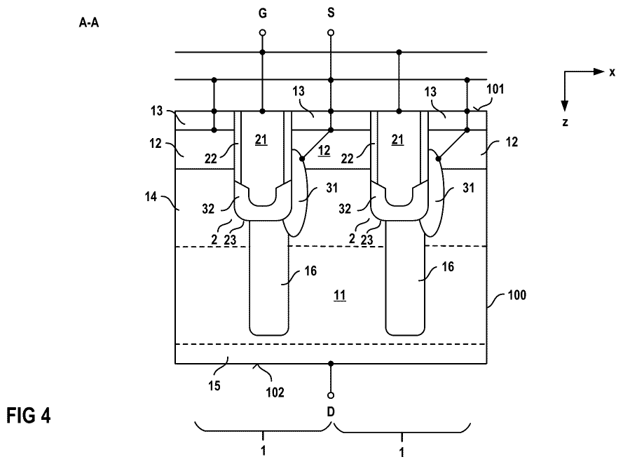

FIG. 4 illustrates a modification of the transistor device illustrated in FIG. 1. The transistor device according to FIG. 4 is implemented as a superjunction device. In this case, each transistor cell 1 includes a compensation region 16 of the second doping type. The compensation region 16 is connected to the source node S. Furthermore, the compensation region 16 adjoins the drift region 11, so that a PN junction is formed between the compensation region 16 and the drift region 11. According to one example, a dimension of the compensation region 16 in the vertical direction z is at least 20% of the dimension (length) of the drift region 11 in the vertical direction z. The doping concentration of the compensation region 16 is in the range of the doping concentration of the drift region 11, for example.

Referring to the above, the compensation region 16 is connected to the source node S. In the example illustrated in FIG. 4 the compensation region 16 adjoins the field shaping a region 31, so that the compensation region 16 is connected to the source node S via the field shaping region 31 and the body region 12. When the transistor device according to FIG. 4 is in the off-state, a depletion region expands also beginning at the PN junctions between the drift region 11 and the compensation regions 16, so that a portion of the dopants included in the drift region 11 are “compensated” by dopants included in the compensation regions 16. Thus, at a given voltage blocking capability, the drift region 11 can be implemented with a higher doping concentration resulting in a lower on-resistance than a conventional (non-superjunction) device. This is a well-known effect so that no further explanation is required in regard.

Referring to FIG. 1, each gate trench 23 has a first sidewall 231 and a second sidewall 232 opposite the first sidewall 231. In the example illustrated in FIG. 1, the field shaping region 31 adjoins the second sidewall 232 and, along the second sidewall 232, extends to or into the body region 12. The gate dielectric 22 may be arranged along both sidewalls 231, 232 of the gate trench 23. In the example according to FIG. 1, however, the field shaping region 31 interrupts a conducting channel in the body region 12 along the second sidewall 232. (Actually, in this example, the body region 12 adjoining the second sidewall 232 of the gate trench 23 of one transistor cell is the body region 12 of the neighboring transistor cell). Thus, in this example, conducting channels in the body regions 12 are only formed along the first sidewalls 231 of the gate trenches 23.

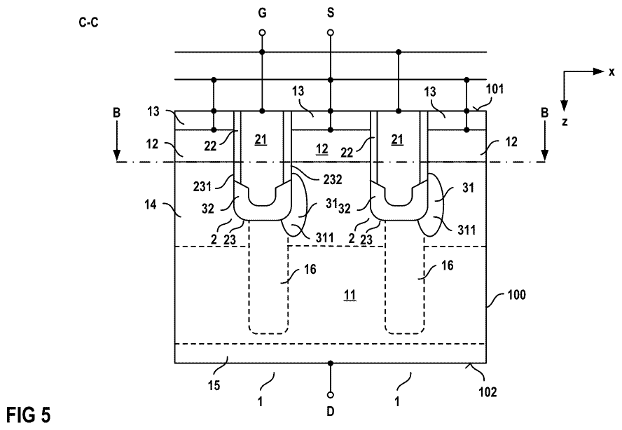

FIG. 5 shows a modification of the transistor device according to FIG. 1. In the transistor device according to FIG. 5, the field shaping region 31 of each transistor cell 1 adjoins the second sidewall 232. However, at least a portion of the field shaping region 31 is spaced apart from the body region 12 in the vertical direction z. In this example, in the on-state of the transistor device, conducting channels between the source region 13 and the drift region 11 are formed along both the first and second sidewalls 231, 232. This reduces the on-state of the transistor device according to FIG. 5 as compared to the transistor device according to FIG. 1.

Sections of the field shaping regions 31 that extend farther in the direction of the first surface 101 than the drift region 11, such as sections of the field shaping regions 31 illustrated in FIGS. 1 and 4, are referred to as first sections (having reference number 310) in the following. The sections of the field shaping regions 31 that are spaced apart from the body regions 12 in the vertical direction z are referred to as second sections 311 in the following.

The second sections 311 are optional. Thus, according to one example, the second sections 311 are omitted. In this example, one field shaping region 31, along the respective gate trench 23, includes several first sections that are spaced apart from each other in the second lateral direction y and are each connected to the source node S.

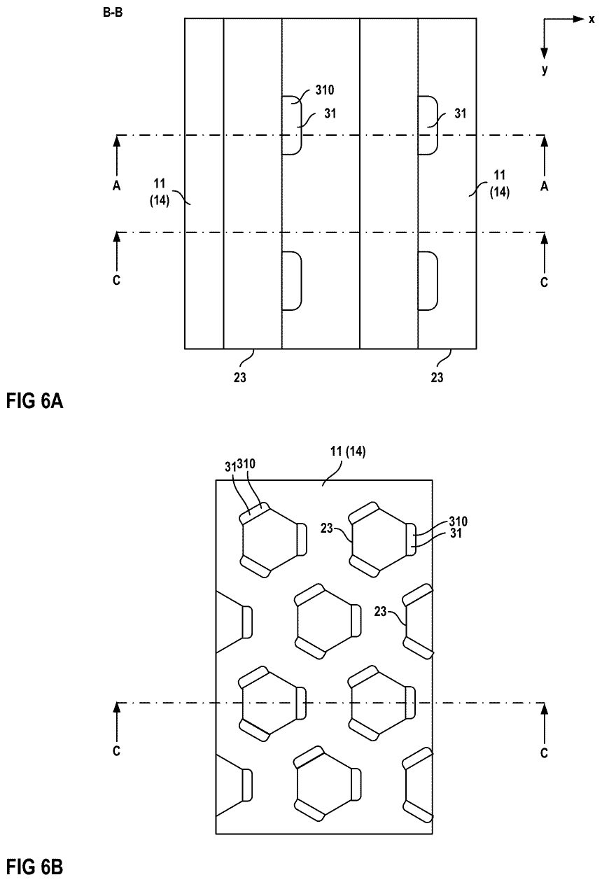

Examples of field shaping regions 31 that have first sections 310 and optionally have second 311 are illustrated in FIGS. 6A and 6B. Each of FIGS. 6A and 6B shows a horizontal cross-sectional view of the transistor device according to FIG. 5 in a horizontal sectional plane B-B that extends along a junction between the body regions 12 and the drift region 11. FIG. 6A shows a transistor device with elongated transistor cells, and FIG. 6B shows a transistor device with hexagonal transistor cells.

Referring to FIGS. 6A and 6B, the field shaping region 31 of each transistor cell includes several sections 310 that extend to the body region 12 (out of view in FIGS. 6A and 6B) and are connected to the source node S. These sections 310 may be referred to as connection sections. Referring to FIGS. 6A and 6B, the connection sections 310 of one field shaping region 31 adjoin the respective gate trench 23 and are spaced apart from each other.

In the example according to FIG. 6A, the connection regions 310 are spaced apart from each other in a longitudinal direction of the gate trench 23. A vertical cross-sectional view of the device illustrated in FIG. 6A in a vertical section plane C-C that is spaced apart from the connection sections 310 corresponds to the vertical cross-sectional view illustrated in FIG. 5. A vertical cross-sectional view in a vertical section plane cutting through the connection sections 310 corresponds to the vertical cross-sectional view illustrated in FIG. 1, for example.

In the example according to FIG. 6B, the connection regions 310 are spaced apart from each other along a circumference of the respective (hexagonal) trench. It should be noted in this regard, that hexagonal gate trenches are only one example of pile-shaped trenches. Other types pile-shaped gate trenches 23, such as gate trenches having a rectangular, or a circular cross-section may be implemented as well. A vertical cross-sectional view of the device illustrated in FIG. 6B in the vertical section plane C-C corresponds to the view illustrated in FIG. 5.

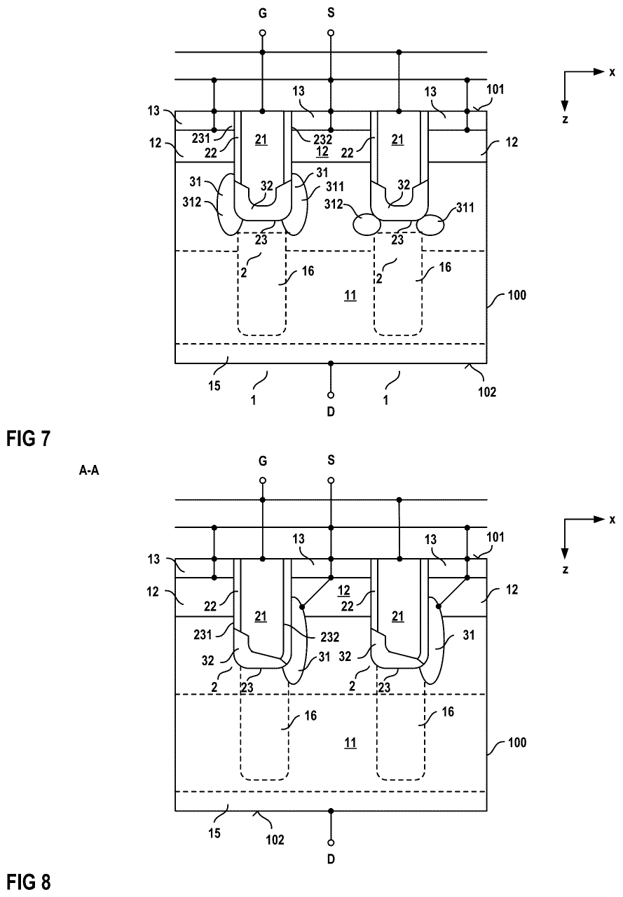

FIG. 7 shows a modification of the transistor device illustrated in FIGS. 5 and 6. In the transistor device according to FIG. 7, each transistor cell 1 includes two field shaping regions 31 of the type illustrated in FIGS. 5 and 6, a first field shaping region 311 that corresponds to the field shaping regions 31 explained herein before and adjoins the second gate trench sidewall 232, and a second field shaping region 312 that adjoins the first gate trench sidewall 231. Each of these first and second field shaping regions 311, 312 can be implemented in accordance with the field shaping region 31 explained with reference to FIGS. 5 and 6A-6B. According to one example illustrated in dashed lines in FIG. 7, the first field shaping regions 311, 312 adjoin each other below the trench bottom.

As illustrated on the left side in FIG. 7, the first and second field shaping regions 311, 312 adjoin sidewall sections and bottom sections of the gate trench 23. This, however, is only an example. According to another example illustrated on the right side in FIG. 7, the first and second field shaping regions 311, 312 essentially only adjoin the trench bottom. In both examples, the first and second field shaping regions 311, 312 are connected to the source node S through respective connection regions which are out of view in FIG. 7.

Referring to the examples explained herein before, the gate trench 23 of each transistor cell 1 may essentially be symmetrical with respect to a center plane of the respective gate trench 23. The “center plane” is a plane extending in the vertical direction z of the semiconductor body 100. According to one example, the first and second field shaping regions 311, 312 are symmetrical to each other relative to the center plane of the gate trench 23.

Referring to the examples illustrated in FIGS. 1 and 4-5, the field dielectric 32 may be implemented to be symmetrical with respect to the center plane of the respective gate trench 23. In each of these examples, the field dielectric 32 entirely covers the bottom of the respective gate trench 23 and extends along a portion of each of the first and second sidewalls 231, 232 in the direction of the body region 12. However, a symmetrical field dielectric 32 is only an example. It is also possible to implement the transistor cells 1 with asymmetrical field dielectrics. One example of an asymmetrical field dielectric 32 is illustrated in FIG. 8.

The transistor device illustrated in FIG. 8 is based on the transistor device illustrated in FIG. 1 and is different from the transistor device according to FIG. 1 in that the field dielectric 32 is asymmetric. This includes that the gate dielectric 22 extends further in the vertical direction z along the second sidewalls 232 than along the first sidewall 231. This includes that the field dielectric 32 extends less far in the direction of the body region along the second sidewall 232 than along the first sidewall 231. In the example illustrated in FIG. 8, the gate dielectric 22, along the second sidewall 232, essentially extends to the trench bottom and is arranged between the gate electrodes 21 and the field shaping a region 31. A portion of the field dielectric 32 adjoins the field shaping region 31, so that at the trench bottom the field dielectric 32 is arranged between the gate electrode 21 and the drift region 11 or the optional compensation region 16. Along the first sidewall 231, the field dielectric 32 extends from the trench bottom in the direction of the body region 12.

In the example according to FIG. 8, large portions of the field shaping regions 31 are separated from the gate electrodes 21 by the gate dielectric 22. This results in a reduced gate-source capacitance as compared to a device with a symmetric field dielectric, in which large portions of the field shaping regions 31 are separated from the gate electrode 21 by the field dielectric 23.

Referring to the above, the source regions 13 and the body regions 12 are connected to the source node S of the transistor device. Two examples for connecting the source regions 13 and the body regions 12 of the transistor cells 1 to the source node S are explained in the following.

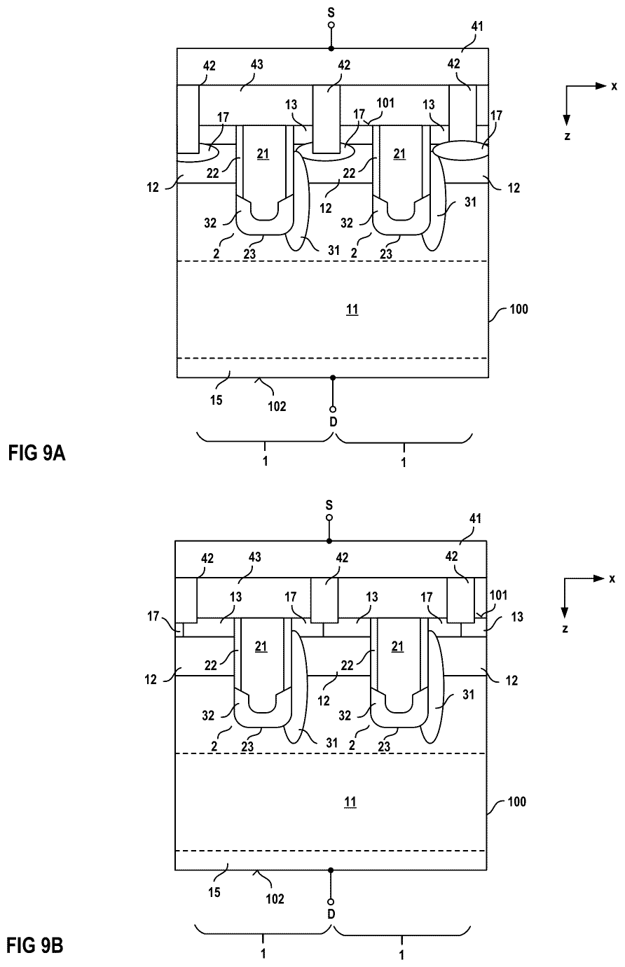

Referring to the above, the field shaping regions 31 are connected to the source node S. Examples for connecting the field shaping regions 31 to the source node S are illustrated in FIGS. 9A and 9B.

In the examples illustrated in FIGS. 9A and 9B, the transistor device includes a source metallization 41 on top of an insulating layer 43. The insulating layer 43 is formed on top of the first surface 101 of the semiconductor body 100 and electrically insulates the gate electrodes 21 from the source metallization 41. The source metallization 41 is connected to the source node S or forms the source node S of the transistor device. Furthermore, the transistor device includes electrically conducting vias 42 that extend through the insulating layer 43 to the semiconductor body 100 and are connected to the source and body region 13, 12, so that the electrically conducting vias 42 connect the source and body regions 13, 12 to the source metallization 41. The electrically conducting vias 42 are also referred to as source vias in the following.

The transistor cells 1 of the transistor devices illustrated in FIGS. 9A and 9B are in accordance with the example illustrated in FIG. 1. This, however, is only an example. The way of connecting the source and body regions 13, 12 to the source metallization 41 illustrated in FIGS. 9A and 9B are independent of the specific implementation of the transistor cells 1. Thus, in the transistor devices according to FIGS. 9A and 9B any other type of transistor cell 1 explained herein before may be used as well.

In the example according to FIG. 9A, the source vias 42 extend through the source regions 13 into the body regions 12. In those regions in which a source via 42 adjoins a body region 12 the body region 12 may have a contact region 17 with a higher doping concentration than in the remainder of the body region 12. The higher doping concentration serves to achieve an ohmic contact between the source via 42 and a respective body region 12. According to one example, the field shaping regions 31 adjoin the contact regions 17, so that the field shaping regions 31 are connected to the source nodes via the contact regions 17 and the source vias 42. The contact regions 17 are spaced apart from the first surface 101 in this example.

In the example according to FIG. 9B, the contact regions 17 are arranged next to the source regions 13 in the lateral direction x, adjoin the body regions 12, and may adjoin the first surface 101. Furthermore, each of the field shaping regions 31 adjoins a respective one of the contact regions 17. Each of the contact regions 17 and the source regions 11 is connected to a respective source via 42.

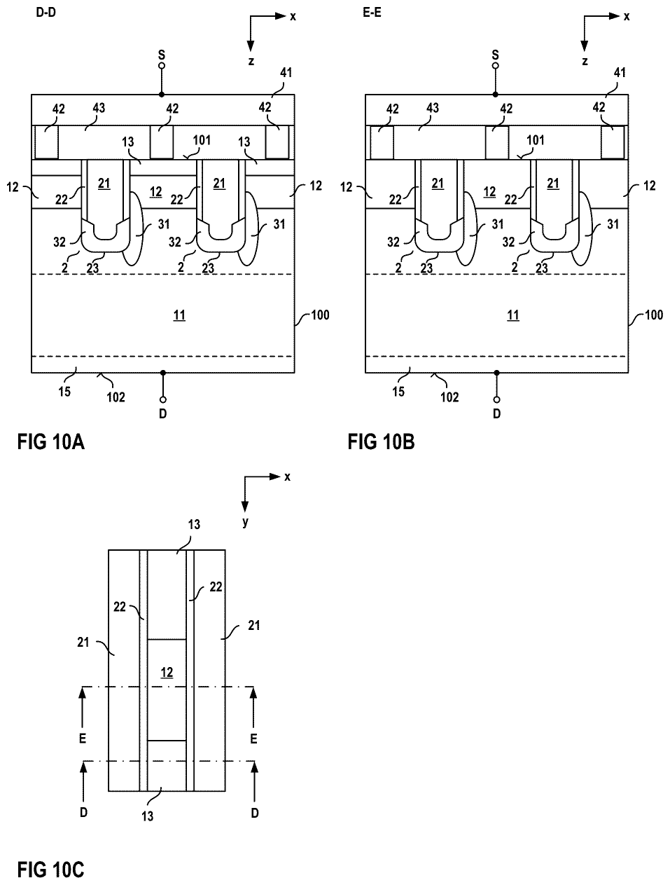

FIGS. 10A-10C illustrate another example for connecting the source and body regions 13, 12 to the source metallization 41. FIG. 10A shows a vertical cross-sectional view of the transistor device in a first section plane D-D, FIG. 10B shows a vertical cross-sectional view of the transistor device in a second section plane E-E, and FIG. 10C shows a top view of the first surface 101 of the semiconductor body 100. The example illustrated in FIGS. 10A-10C is different from the example illustrated in FIG. 9 in that the source vias 42 extend to or into the source regions 13, but do not extend through the source regions 13 to the body regions 12. In this example, the body regions 12 include sections that extend to the first surface 101, wherein the sections of the body regions 12 extending to the first surface 101 are connected to the source vias 42 in order to connect the body regions 12 to the source metallization 41.

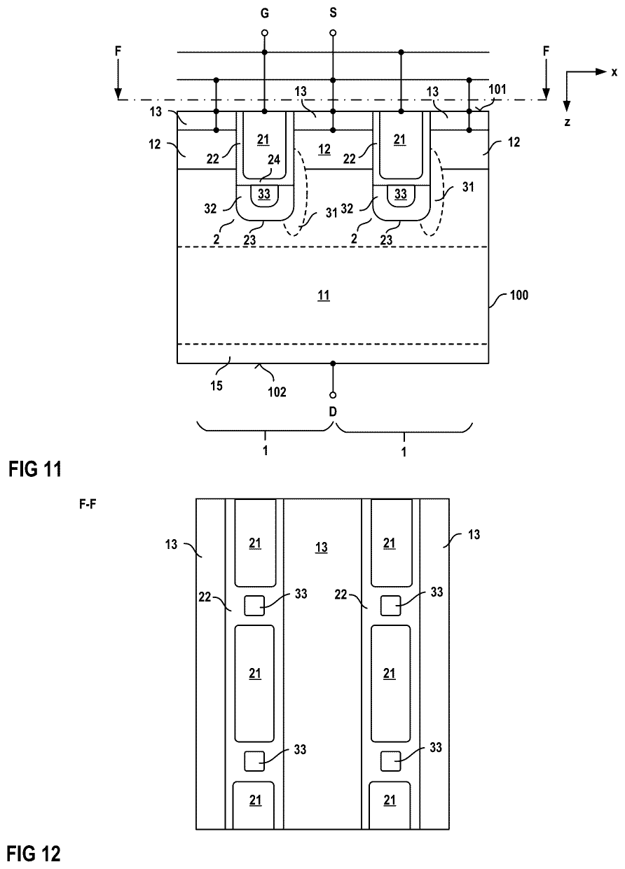

FIG. 11 shows a vertical cross-sectional view of a transistor device according to another example. The transistor device according to FIG. 11 is based on the transistor device according to FIG. 1 and is different from the transistor device according to FIG. 1 in that each transistor cell 1, in addition to the field dielectric 32, includes a field electrode 33. The field electrode 33 is arranged in the gate trench 23 and, as seen from the first surface 101, is arranged below the gate electrode 21 and the body region 12. The field electrode 33 is dielectrically insulated from the drift region 11 by the field dielectric 32 and is insulated from the gate electrode 21 by a further dielectric layer 24. According to one example, the further dielectric layer 24 includes the same material as the gate dielectric 22.

Referring to FIG. 11, each transistor cell may include a field shaping region 31. The field shaping region 31, however, is optional and is therefore illustrated in dashed lines in FIG. 11. The field shaping regions 31 illustrated in FIG. 11 are implemented in accordance with the example illustrated in FIG. 1. This, however, is only an example. Any other type of field shaping regions 31 explained herein before may be used in the transistor device according to FIG. 11 as well.

The field dielectric 32 is a high-k dielectric. Everything explained herein before with regard to the field dielectric 32 applies to the field dielectric 32 according to FIG. 11 accordingly. The functionality of the transistor device according to FIG. 11 is similar to the functionality of the transistor device explained herein before. As compared to the transistor device explained herein before, the transistor device according to FIG. 11 has a lower gate-drain capacitance, which is the capacitance between the gate node G and the drain node. This applies, in particular, when the field electrode 33 is connected to the source node S.

In order to connect the field electrode 33 to the source node S, the field electrode 33 may include sections that extend to the first surface 101 of the semiconductor body 100. FIG. 12 shows a top view of the first surface 101 of a transistor device in which sections of the field electrode 33 extend to the first surface 101.

The sections of the field electrode 33 extending to the first surface 101 are connected to the source node S. According to one example, the transistor device includes a source metallization 41 (not illustrated in FIGS. 11 and 12) of the type explained herein before. In this example, the sections of the field electrode 33 extending to the first surface 101 can be connected to the source metallization using source vias in the same way as explained herein before with regard to the source regions 13.

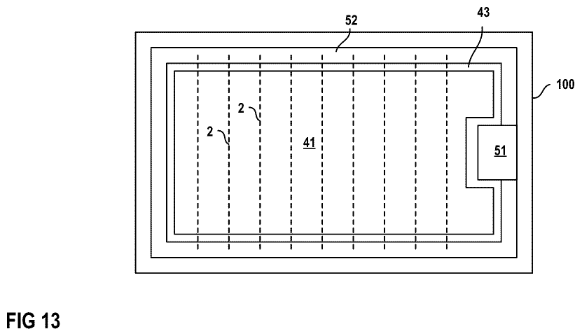

FIG. 13 shows a top view of the transistor device according to any one of the examples explained herein before. More specifically, FIG. 13 shows a top view of the semiconductor body 100 with the source metallization 41. Examples of the gate structures 2 and their position below the source metallization 41 are illustrated in dashed lines in FIG. 13. In this example, the gate structures 2, below the source metallization 41, extend beyond the source metallization 41 and are connected to a gate runner 52. The gate runner 52 is formed on top of the insulating layer 43 and is connected to a gate pad 51. The gate pad 51 is connected to the gate node G or forms the gate node G of the transistor device.

The transistor device according to FIG. 13 includes only one source metallization 41. This, however, is only an example. According to another example (not illustrated) the transistor device includes several source metallizations, which are each connected to the source node S, and includes two or more gate runners 52, which are each connected to the gate pad 51. Several gate runners may be used in a transistor device of the type illustrated in FIG. 12, for example. In this transistor device, the field electrode sections that extend to the first surface 101 interrupt the gate electrodes 21, so that each of the different sections of the gate electrodes need to be connected to a respective gate runner.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device comprising a semiconductor body and plurality of transistor cells, wherein each transistor cell comprises:
a drift region and a source region of a first doping type;
a body region of a second doping type complementary to the first doping type;
a field shaping region of the second doping type connected to a source node;
a gate electrode connected to a gate node,
wherein the gate electrode is arranged in a trench extending from a first surface into the semiconductor body,
wherein the gate electrode is dielectrically insulated from the body region by a gate dielectric,
wherein at least portions of the gate electrode are dielectrically insulated from the drift region by a field dielectric,
wherein the field shaping region adjoins the trench, and
wherein the field dielectric comprises a high-k dielectric.

2. The transistor device of claim 1,
wherein the field shaping region, in a vertical direction of the semiconductor body, extends deeper into the semiconductor body than the trench.

3. The transistor device of claim 1,
wherein the body region is connected to the source node, and
wherein the field shaping region adjoins the body region to be connected to the source node via the body region.

4. The transistor device of claim 1,
wherein the body region is connected to the source node via a contact region having a higher doping concentration than a remainder of the body region, and
wherein the field shaping region adjoins the contact region to be connected to the source node via the contact region.

5. The transistor device of claim 1,
wherein the field shaping region includes a plurality of first sections that are spaced apart from each other along a sidewall of the trench and that are each connected to the source node.

6. The transistor device of claim 5,
wherein the first sections, in a vertical direction of the semiconductor body, extend farther in a direction of the first surface than the drift region.

7. The transistor device of claim 6,
wherein the field shaping region further comprises second sections that adjoin the first sections and are spaced apart from the body region.

8. The transistor device of claim 1,
wherein the field dielectric is symmetrical relative to a center plane of the trench.

9. The transistor device of claim 1,
wherein the field dielectric is asymmetrical relative to a center plane of the trench.

10. A transistor device comprising a semiconductor body and plurality of transistor cells, wherein each transistor cell comprises:
a drift region and a source region of a first doping type;
a body region of a second doping type complementary to the first doping type;
a gate electrode connected to a gate node;
wherein the gate electrode and the field electrode are arranged in a trench extending from a first surface into the semiconductor body,
wherein the field electrode is dielectrically insulated from the gate electrode in the trench,
wherein the gate electrode is dielectrically insulated from the body region by a gate dielectric,
wherein the field electrode is dielectrically insulated from the drift region by a field dielectric, and
wherein the field dielectric comprises a high-k dielectric.

11. The transistor device of claim 10, further comprising:
a field shaping region of the second doping type connected to a source node.

12. The transistor device of claim 11,
wherein the field shaping region adjoins the trench and, in a vertical direction of the semiconductor body, extends deeper into the semiconductor body than the trench.

13. The transistor device of claim 10,
wherein the field electrode is connected to a source node.

14. The transistor device of claim 10,
wherein each transistor cell further comprises a compensation region of the second doping type,
wherein the compensation region adjoins the drift region.

15. The transistor device of claim 14, further comprising:
a field shaping region of the second doping type connected to a source node,
wherein the compensation region adjoins the field shaping region.

16. The transistor device of claim 10,
wherein a maximum thickness of the gate dielectric is smaller than a maximum thickness of the field dielectric.

17. The transistor device of claim 10,
wherein the gate dielectric comprises silicon dioxide.

18. The transistor device of claim 10,
wherein the gate dielectric comprises a high-k dielectric.

19. The transistor device of claim 10,
wherein a relative dielectric constant of the high-k dielectric is higher than 5, higher than 10, or higher than 20.

20. The transistor device of claim 10, wherein the semiconductor body is a SiC semiconductor body.
